(19) United States
(12) Patent Application Publication
(10) Pub. No.: US 2010/0078628 A1
(43) Pub. Date: Apr. 1, 2010

(54) UNIVERSAL METHOD FOR SELECTIVE AREA GROWTH OF ORGANIC MOLECULES BY VAPOR DEPOSITION

(76) Inventors: Lifeng Chi, Munster (DE); Wengchong Wang, Munster (DE); Dingyong Zhong, Munster (DE); Harald Fuchs, Munster (DE)

Correspondence Address: SYLKE LAW OFFICES, LLC, 756 N. MILWAUKEE STREET, SUITE 210, MILWAUKEE, WI, 53202, US

(21) Appl. No.: 12/517,795

(22) PCT Filed: Dec. 5, 2007
(86) PCT No.: PCT/EP07/10568

§ 371 Date: Jun. 4, 2009

(30) Foreign Application Priority Data
Dec. 6, 2006 (GB) 0624376.0

(51) Int. Cl. H01L 51/40; H01L 51/30

(52) U.S. Cl. 257/40; 438/99; 257/E51.024

(57) ABSTRACT

A method for selective growth of organic molecules on a substrate is proposed. The method comprises: creating a pattern of nucleation sites for the organic molecules on the substrate; depositing of organic molecules at the nucleation sites by vapor deposition. An organic material based device obtained by performing the method is also proposed. The method offers an alternative to methods that are known the fields of coating technology or semiconductor fabrication.

### FIELD OF THE INVENTION

The invention relates to a method of selective growth of organic molecules on a substrate.

The invention further relates to an organic material based device obtained by this method.

### BACKGROUND TO THE INVENTION

For the past fifty years inorganic IV and III-V species semiconductors have been the backbone of the semiconductor industry. However, organic semiconductors have attracted tremendous interest recently due to the ease of manufacturing and potential low cost compared to their inorganic peers. The organic semiconductors are already in use in organic light emitting diodes (OLEDs), Organic field effect transistors (OFETs), photovoltaic devices, and organic semiconductor lasers. Products based on organic semiconductors are already in the market. However, the future success of the organic materials will greatly depend on the fabrication and packaging of devices which are, in most cases, dominant in cost of the electronics.

Typically, organic semiconductor materials can be classified into small molecules with a well-defined molecular weight and polymers consisting of a large number of molecular repeat units. Polymers allow use of simple process techniques such as spin-coating and printing. In contrast, small molecule semiconductors currently show superior properties such as mobility. Both materials are interesting depending on the application. Physical vapour deposition, in which organic molecules are evaporated from a hot Knudsen cell to a relatively cold substrate is the most common means for depositing small molecular weight semiconductor due to their poor solubility in common solvents. Physical vapour deposition allows the tailoring of the device structure with excellent uniformity and sharp interfaces, high material purity, and high efficiency of utilizing raw material.

In many device applications, the active device area must be patterned with a lateral resolution ranging from nanometer scale to micrometer scales. The technologies of patterning have been well developed for the inorganic semiconductors by combination of lithography and etching. The photolithographic patterning of organic molecular devices has to date been difficult due to degradation or complete failure of the devices after being exposed to water vapour, oxygen, or solvents and developers used in the removal or patterning of the photo-resists. Several methods of patterning have been developed to overcome this problem. Forrest et al. demonstrated resolution of micrometers range by using shadow mask for example in “Precise, scalable shadow mask patterning of vacuum-deposited organic light emitting devices”, Journal of Vacuum Science & Technology A: Vacuum, Surfaces, and Films—September 1999—Volume 17, Issue 5, pp. 2975-2981. The method in this publication requires precise shadow mask fabrication and handling in vacuum. It is very difficult to fabricate shadow masks for miniature devices with size of few micrometers with large area. Alternatively, a stamping method was applied for patterning devices with resolution of tens of micrometers. However, the stamping method is not uniform and areas with defects frequently appeared. Excimer laser photoablation has also been used for patterning organic devices with efficient resolution, but this method may not be capable for mass production due to its low speed.

Selective area growth is a tool for the fabrication of new electronic, optoelectronic and photonic devices for organic semiconductors. Selective area growth allows the organic material preferentially grown on desired areas by using a mask, self-assembly, surface modification or phase separation. It leads to the fabrication of complex self-aligned device structures, greatly simplifies the subsequent processing and is widely used in inorganic semiconductor epitaxy, nanotube growth, controlling of crystal nucleation and Langmuir-Blodgett technique. However, the selective area growth technique has not yet been applied for patterning and processing organic semiconductor devices.

Japanese Patent JP7069793 discloses a method for selective growth of an inorganic carbon crystal on a semiconductor substrate or a carbon crystal substrate. According to the method of JP7069793 an insulating mask is formed on the surface of the substrate. The substrate is then subjected to epitaxial growth in a vapour phase which leads to the growth of carbon crystals on the non-insulated areas of the substrate. The insulating mask is actually a negative representation of the pattern of the nucleation sites.

### SUMMARY OF THE INVENTION

The invention disclosed herein proposes a method for selective area growth of organic molecules on a substrate comprising:
creating a pattern of nucleation sites for organic molecules on the substrate;
depositing of organic molecules at the nucleation sites by vapour deposition.

One of the underlying principles of the method of selective area growth is that a molecule will look for energy favourable sites (so-called nucleation sites) as the molecule reaches and diffuses on a surface of a substrate. The nucleation sites could be step edges, defects, nucleus of molecules, or pre-designed patterns that cause the settling down of the molecules. The molecules will nucleate at the nucleation sites if an energy favourable site is found. By the intentional introduction of energy traps for surface diffusion and choosing the selected growth parameters, the molecules can be controlled to grow on desired areas, i.e. the nucleation sites.

Selective area growth causes the organic material to grow preferentially on the desired areas. The method of the invention can achieve a very high resolution. The proposed method for selective area growth exhibits an efficient utilization of raw materials. In the context of the selective area growth it is not necessary to expose the device to aggressive environments as is the case with photolithographic patterning. Accordingly, the deposited organic molecules are not degraded during removal or patterning of photo-resists. The proposed method also provides for cost-effective and timesaving fabrication and packaging of devices that are based on organic semiconductors.

The method may further comprise controlling the deposition of the organic molecules by adjusting a temperature of the substrate. The temperature of the substrate has a great influence on the selectivity. Selectivity is a measure for the discrimination of the molecules with respect between the nucleation sites and the remainder of the substrate surface. The degree of selectivity is higher for higher substrate temperatures, because the hopping probability of the molecule from one location to another location by overcoming a potential barrier is a thermally activated process. The molecules receive more energy at higher temperatures of the substrate. As a result, the molecules can move longer distances before adsorption at the surface.

The method may further comprise controlling the deposition of the organic molecules by adjusting a growth rate of the organic molecules. The growth rate is another growth parameter for the degree of selectivity. The growth rate is controlled, among other parameters, by the number of molecules that are available for nucleation at the nucleation sites or adsorption on the remaining substrate. If more of the molecules are available for nucleation, the average diffusion length decreases and increases the number of unintended nucleation sites. The term “unintended nucleation sites” is implied to mean those sites at which no nucleation site was intended by the pattern of nucleation sites. Therefore, the nucleation sites that are part of the pattern of nucleation sites can also be termed “intended nucleation sites” or “planned nucleation sites”.

The growth rate may be adjusted by adjusting a temperature of a hot Knudsen cell used for vapor deposition. Knudsen cells facilitate the preparation of organic thin films by evaporation in high vacuum (HV) and ultra high vacuum (UHV) systems. The material to be deposited is heated to provide a suitable vapor pressure in an enclosure. The temperature of the enclosure determines the deposition rate.

The substrate may be selected from the group consisting of silicon, silicon oxide, indium tin oxide (ITO), glass, aluminum oxide, or chemically modified substrate of above mentioned materials. The material of the substrate has a relatively strong influence on the selectivity. High selectivity of the molecule is achievable by using an inert substrate due to weak interaction of the molecules with the substrate.

The creation of the nucleation sites may comprise the use of a method selected from the group of e-beam lithography, optical lithography, soft lithography, or scanning probe lithography.

The e-beam (electron beam) lithography technique allows the formation of features in the sub-micrometer regime. The width of the electron beam may be in the order of nanometers. For most applications the e-beam lithography is considered to be a relatively slow lithography method, because the electron beam must be scanned across the entire surface to be patterned. However, the speed of the e-beam lithography depends on the density of the structures to be written. If the lateral dimensions of the nucleation sites can be kept relatively small, e-beam lithography may still be competitive in terms of speed, since only a small fraction of the entire surface needs to be processed by the electron beam.

Optical lithography is a fast technology for transferring a pattern from a photomask to the surface of the substrate. If the structures to be written are sufficiently large, optical lithography therefore is an option for creating nucleation sites on the substrate.

Soft lithography, e.g. contact printing and nanoimprinting, is yet another possible technology for the creation of nucleation sites on the substrate. This variety of lithography uses elastomeric materials or Silicon as stamps. Soft lithography is cost-efficient especially for mass production and allows the definition of small features (down to 30 nm).

In scanning probe lithography a microscopic stylus is mechanically moved across the surface of the substrate, either by mechanically deforming a soft film on the surface designed for this purpose, or by transferring a chemical species too the surface.

The creation of the nucleation sites may comprise depositing a nucleation material as the nucleation site on the substrate. If a suitable one of the nucleation material is chosen, the nucleation effect is enhanced. The nucleation material is for example suitable if on the surface of the nucleation material a strong adsorption of the molecules can be observed.

The nucleation material may be gold or other materials that have different surface energy than the substrate. This may lead to an increased selectivity of the selective area growth method which is normally desired in the execution of the method.

In the further course of the method, the deposition of organic molecules may be performed in vacuum by physical vapor deposition or chemical vapor deposition. Physical vapor deposition (PVD) by which the organic molecules are evaporated from a hot Knudsen cell to a relatively cold substrate, is the most common means for depositing small molecular weight semiconductors. This technology has advantages to tailor the device structure with excellent uniformity and sharp interfaces, high material purity, and high efficiency of utilizing raw material. A low-pressure vapor environment such as vacuum assists the physical vapor deposition process to function properly. In chemical vapor deposition (CVD) a gas-phase precursor is used, typically at very low pressures.

The organic molecules may be aromatic molecules. These molecules show weak interaction with the SiO₂ as substrate material. Hence, the aromatic molecules are less likely to nucleate outside of the nucleation sites, leading to higher selectivity of growth.

The organic molecules may be molecules of an organic semiconductor. The organic semiconductors are nowadays regarded as an alternative to the inorganic semiconductors. The fabrication of the organic semiconductors is expected to be easy and cost-efficient.

The invention also envisages an organic material based device obtained by performing the method of the invention. One possible application is an organic semiconductor, a semiconductor made from carbon-based material. These organic material based devices are expected to be competitive with their inorganic peers in terms of easy of manufacture and cost. This is in part also achieved by the utilization efficiency of the raw material when using the selective area growth method for manufacturing an organic material based device. The material can be controlled to deposit on the desired area.

The organic material based device may be selected from the group consisting of organic light emitting diodes, organic field effect transistors, photovoltaic devices, or organic semiconductor lasers. The mentioned devices can be created on a multitude of suitable substrates by means of the described method. It is also possible to provide flexible materials as substrate which renders possible the integration of such devices in e.g. roll-up displays or clothing.

### DESCRIPTION OF THE FIGURES

FIG. 1 shows a schematic representation of the fabrication process.

FIGS. 2A to 2D show atomic force microscopy (AFM) images of NPB deposited at 140° C. and different spacings on SiO₂ which is patterned with gold dots.

FIG. 3A shows an AFM image of NPB on gold substrate.

FIG. 3B shows an AFM image of NPB on SiO₂ substrate.

FIGS. 4A and 4B show images of Diferrocene and NPB grown on SiO₂ substrate at room temperature.

FIGS. 5A to 5C show images of NPB grown on patterned SiO₂ at different temperatures.

FIGS. 6A and 6B show images of NPB grown on gold patterned SiO₂ at different growth rates.

FIG. 7A shows a fluorescent microscopy image of NPB grown on gold patterned SiO₂ substrate.

FIG. 7B shows a fluorescent microscopy image of (dppy)BTPA grown on gold patterned SiO₂ substrate.

FIG. 7C shows a fluorescent microscopy image of DtCDQA grown on gold patterned SiO₂ substrate.

FIGS. 8A to 8D show the structural formulas of organic materials that can be used in a selective area growth method.

### DETAILED DESCRIPTION OF THE FIGURES

The present invention can be explained by the thermodynamic theory of film growth. There are three types of growth mode when molecules are deposited on a solid substrate according to the interaction of the molecule and the solid substrate: Island growth mode, layer-by-layer growth mode, and layer plus island growth mode. The island growth mode can be observed while the interaction between the solid substrate and the molecule to be deposited is weak. Layer plus island growth mode, a combination in which layer growth mode changes to island growth mode after one or several monolayer(s), can be observed with strong interaction between the molecule and the solid substrate. Layer-by-layer growth mode can be achieved if the interaction between the molecules and the solid substrate is medium. The growth mode and average diffusion length of molecules can be controlled by changing the solid substrate, the growth parameters, e.g. substrate temperature and growth rate.

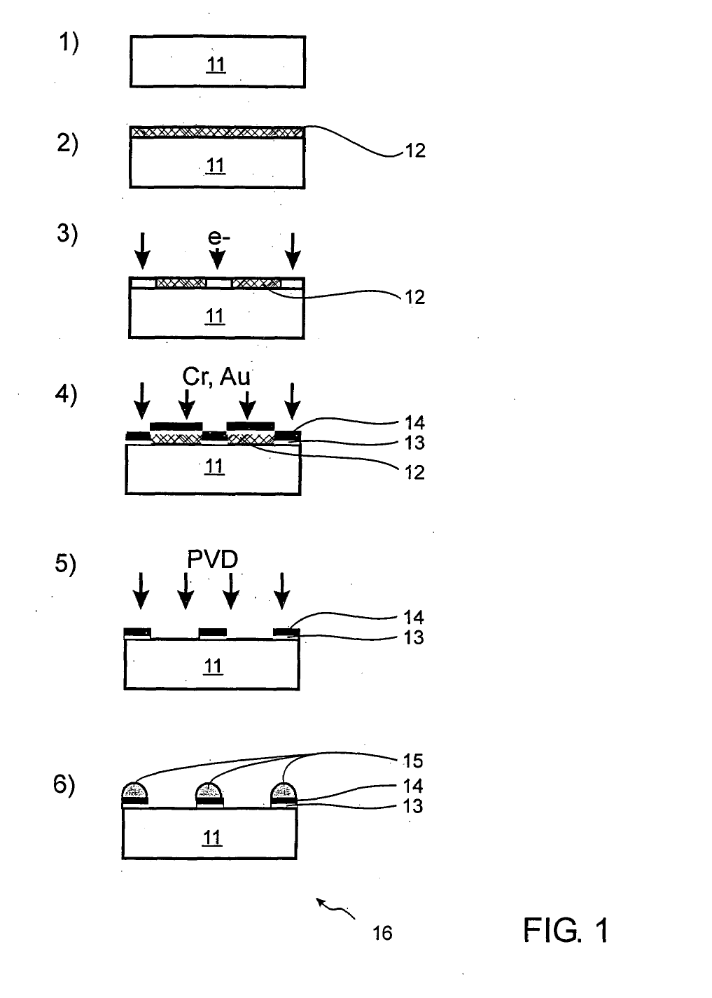

FIG. 1 depicts a fabrication process of the present invention. The process started off with a substrate 11 in step 1) of FIG. 1. In step 2), a resist of poly methyl methacrylate (PMMA) 12 was first deposited on the surface of the substrate 11, and in step 3) dots with different diameter and spacing were defined on the resist using e-beam lithography. In step 4) of FIG. 1, gold (Au) 14 of nanometers in thickness was then deposited to act as nucleation sites for organic molecules. A thin layer of chrome (Cr) 13 was also deposited between substrate 11 and gold 14 for better adhesion. The resist layer 12 was lifted off in acetone by sonication and the sample was cleaned in organic solvent. Finally, the sample was loaded into vacuum for molecule deposition. Molecules were deposited at the nucleation sites by physical vapor deposition (PVD) in step 5) of the process. Step 6) in FIG. 1 shows the resulting organic material based device 16 with the organic molecules 15 grown on the gold nucleation sites 14.

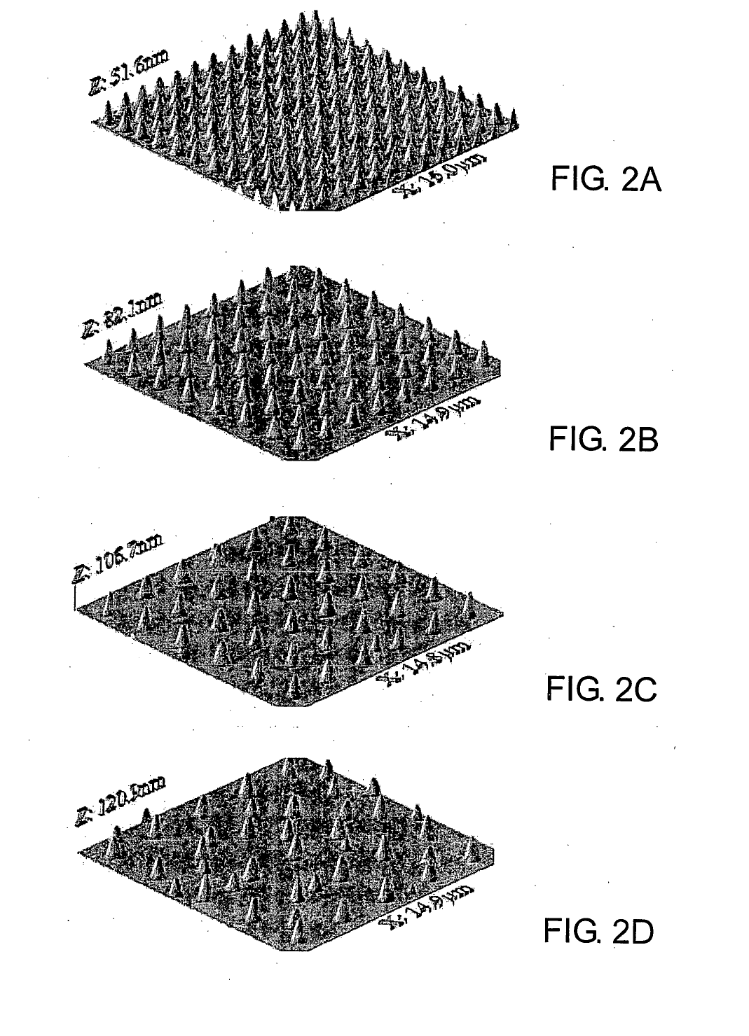

FIG. 2 shows atomic force microscopy (AFM) images of NPB grown on an SiO₂ substrate that is patterned with gold dots forming gold nucleation sites and each one of the gold dots measuring approximately 600 nm in diameter. The spaces between the gold dots are 0.6 um in FIG. 2A, 1.2 um in FIG. 2B, 1.8 um in FIG. 2C, and 2.4 um in FIG. 2D. All of the selectivity was achieved when the gold dots are spaced shorter than 1.2 um apart. Extra nuclei other than intentionally introduced ones of the gold dots begin to appear when the gold dots are spaced further than 1.8 um apart, and become more prevalent as the space between the gold dots increases.

The creation of extra nuclei is due to the fact that the molecules can climb up and nucleate when they reach the gold dots with periodicity shorter than the average diffusion length. Some of the molecules would begin to stop moving and nucleate on the SiO₂ substrate before the molecules reach the gold dots when the periodicity (i.e. distance between the gold dots)) is longer than an average diffusion length of the molecules. The longer periodicity of the gold dots, the less chance there is that the molecules reach the gold dots, resulting in more nuclei between the dots.

N,N′-bis-(1-naphyl)-N,N′-diphenyl-1,1′-biphenyl′-4,4′-diamine (NPB) was also used as a model to investigate the molecular behaviours on the SiO₂ surface. The important parameters to control the degree of the selectivity are the following: the substrate, the molecule, the substrate temperature, and the growth rate.

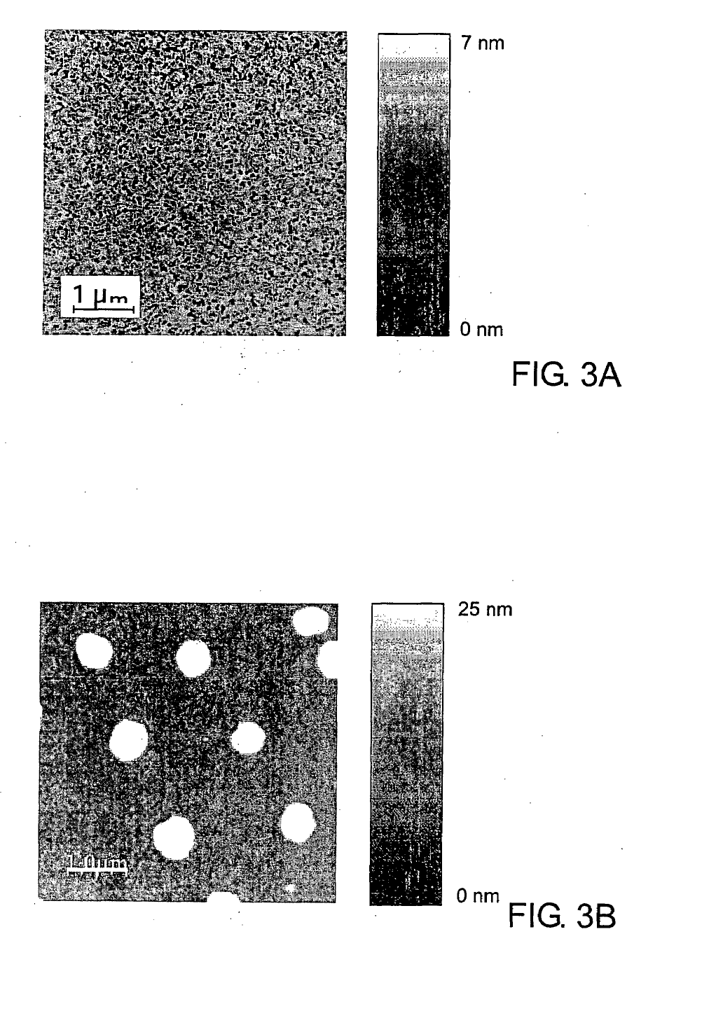

First, the substrate has a strong influence on the selectivity. High selectivity of a molecule could be achieved by using an inert substrate due to weak interaction of the molecules with the substrate. FIG. 3A shows the AFM images of NPB grown on the gold dots and SiO₂ substrate at 140° C. The growth rate was kept for 0.1 nm/min and growth time was 20 min. The gold dots with a neighbours distance of 1.8 um were achieved for NPB on SiO₂, as shown in FIG. 3B. A film like morphology was observed for molecules depositing on gold as shown in FIG. 3A which can be ascribed to the strong adsorption of NPB on the gold surface, which inhibits the molecule migration on the surface of the substrate.

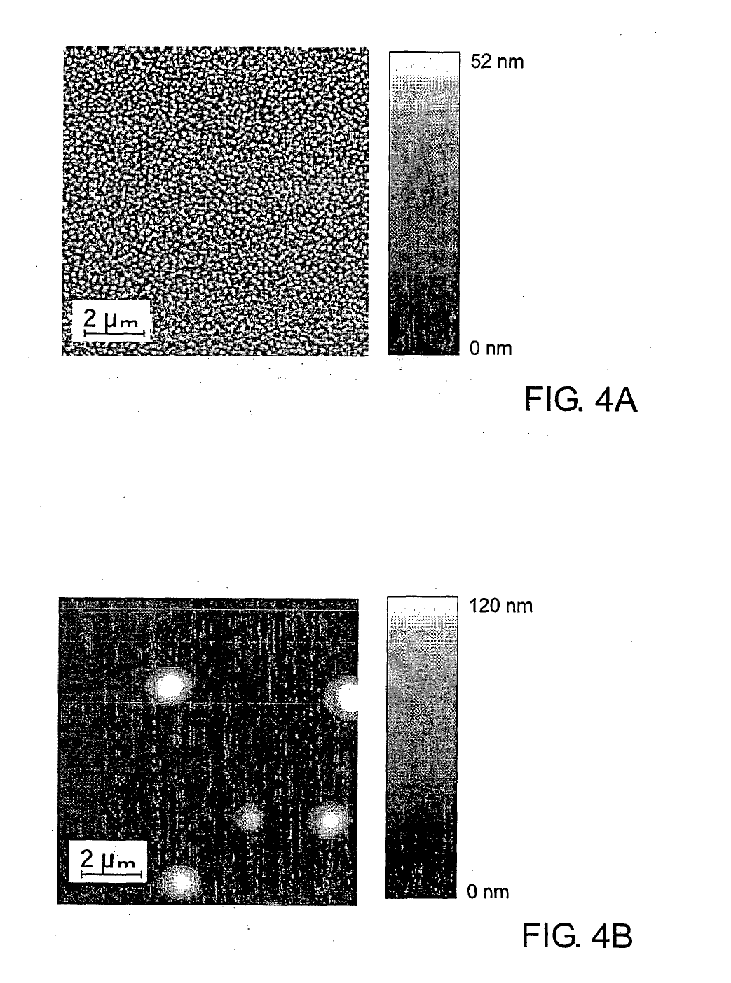

Similarly, the type of the molecule can also affect the growth mode due to the different interaction of different ones of the molecules and the substrate. FIG. 4A shows the AFM images of NPB on the SiO₂ substrate at room temperature. FIG. 4B shows the AFM images of diferrocene on the SiO₂ substrate at room temperature. The growth rate was kept at 0.1 nm/min and growth time was 20 min. Closely packed gold dots were formed for NPB, which indicate a very short distance that NPB molecules can move by this temperature. The dots with first neighbour distance of 3.8 um were formed for diferrocene. This may be ascribed to the weak interaction of the NPB molecules with the SiO₂ substrate and the NPB molecules get less nucleating chances and higher growing selectivity.

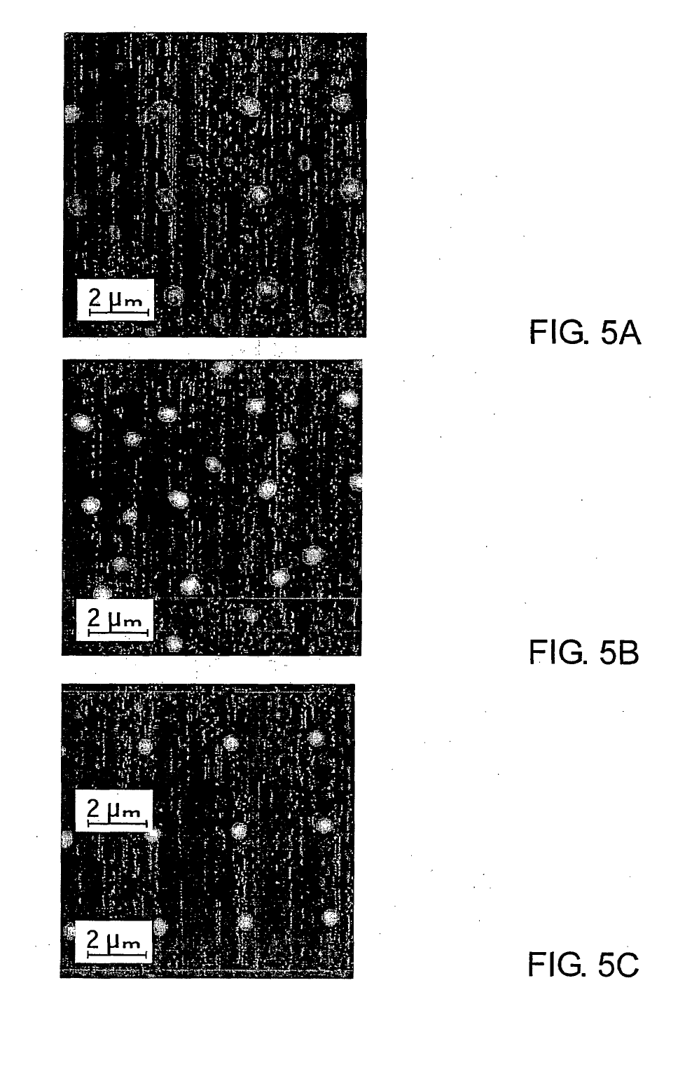

Among growth parameters, the substrate temperature has a great influence on the selectivity. The degree of selectivity is higher for higher substrate temperature. FIGS. 5A to 5C show the NPB molecules grown on the gold dot patterned substrate at 130° C. (FIG. 5A), 140° C. (FIG. 5B) and 145° C. (FIG. 5C). The pattern is an array of the gold dots of 600 nm in diameter and 3 um in distance. Many nuclei between the gold dots were formed for the sample grown at 130° C., and they become less and less as the temperature increased. This is due to the low diffusivity of the molecules on the surface at low temperature. The hopping probability of the molecule from one location to another location by overcoming a potential barrier is a thermally activated process. The higher the substrate temperature, the more energy the molecules can receive, and the longer distance the molecules can move.

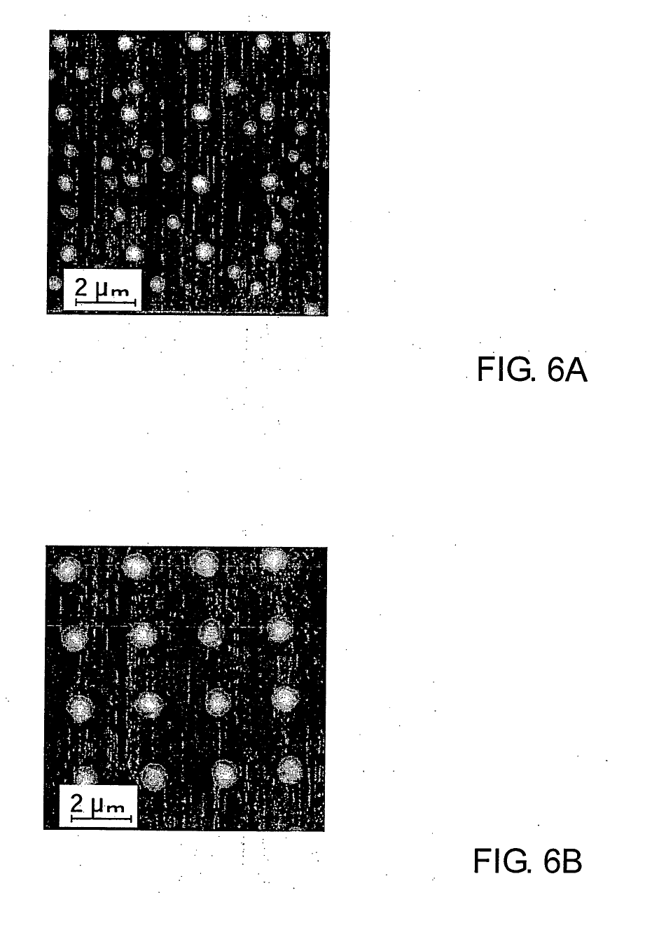

Growth rate is another important growth parameter for the degree of selectivity. FIGS. 6A and 6B show the AFM images of the NPB molecules grown on gold dot patterned SiO₂ substrate at 0.3 and 0.1 nm/min respectively. The substrate temperature is 140° C. and the pattern consists of the array of the gold dots. The gold dots are 600 nm in diameter and spaced at 2.4 um. All of the NPB molecules move to the gold dots for low growth rate of 0.1 nm/min, while the selectivity is much lower for the higher growth rate of 0.3 nm/min. This can be explained by that more NPB molecules are available for nucleation, which would lead to the decrease of the average diffusion length and increase the nucleation sites, as shown in FIG. 6A.

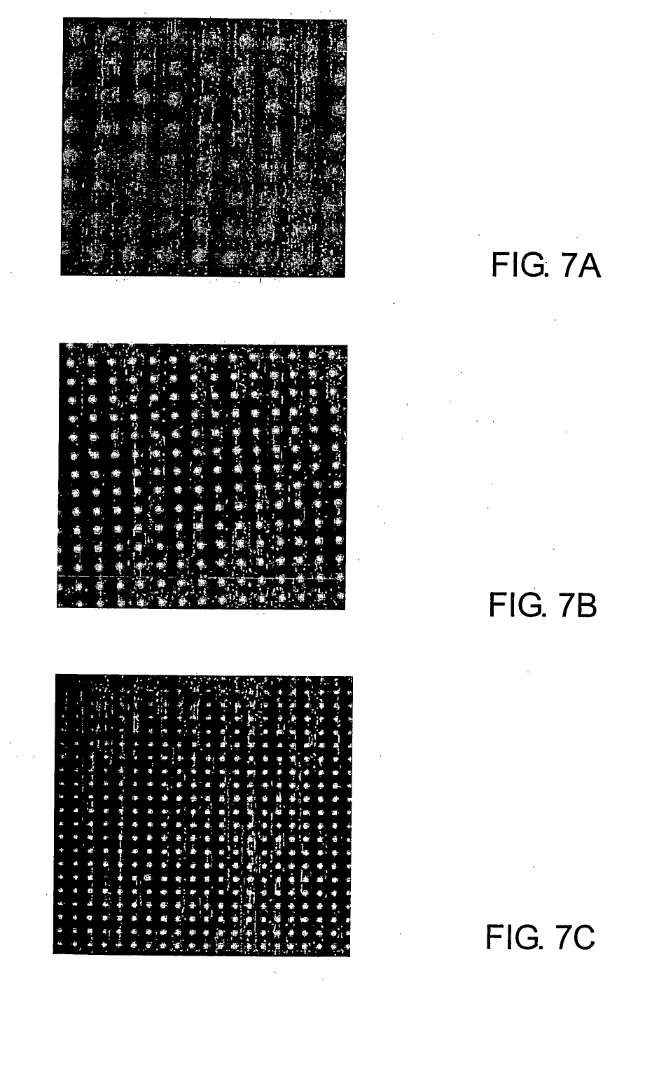

This technique can be easily extended to other molecules just by changing the growth parameters such as the growth temperature and the growth rate. FIG. 7A shows fluorescent microscopy images of the NPB molecules on the gold patterned SiO₂ substrate. FIG. 7B shows the fluorescent microscopy images of (dppy)BTPA on the gold patterned SiO₂ substrate. FIG. 7C shows the fluorescent microscopy images of DtCDQA on the gold patterned SiO₂ substrate. The growth rate and substrate temperature for NPB, (dppy)BTPA and DtCDQA are 0.1 nm/min and 140° C., 0.1 nm/min and 120° C., 0.2 nm/min and 180° C. respectively. The geometrical parameters of the pattern of the gold dots are shown in the figures. The excellent selectivity of different molecules indicates that this technique can be applied to other organic molecules and other solid substrates.

Furthermore, the utilization efficiency of the raw material is improved greatly by using the selective area growth method. In conventional semiconductor device fabrication, a part of the material is wasted by being etched off or in non-active area that plays no role in operation of the devices. With the present invention, the material can be controlled to deposit on the desired area(s). In FIG. 2C as an example, the height of the organic island is about 100 nm, while the average thickness of the film is 1.2 nm, which means that more than 98% of material can be saved.

### Material and Fabrication Methods:

Diferrocene was synthesized by chemical department of Muenster University of Germany; the molecules of NPB, (dppy)BTPA and DtCDQA were synthesized by Key Laboratory for Supramolecular Structure and Materials of Ministry of Education, College of Chemistry, Jilin university, Changchun of China. Poly (methyl methacrylate) (PMMA), 950K, was purchased from All Reist GmbH. The silicon wafers with a 300 nm thermally oxidized SiO₂ were purchased from Si-mat Company. All the chemicals were used without further purification.

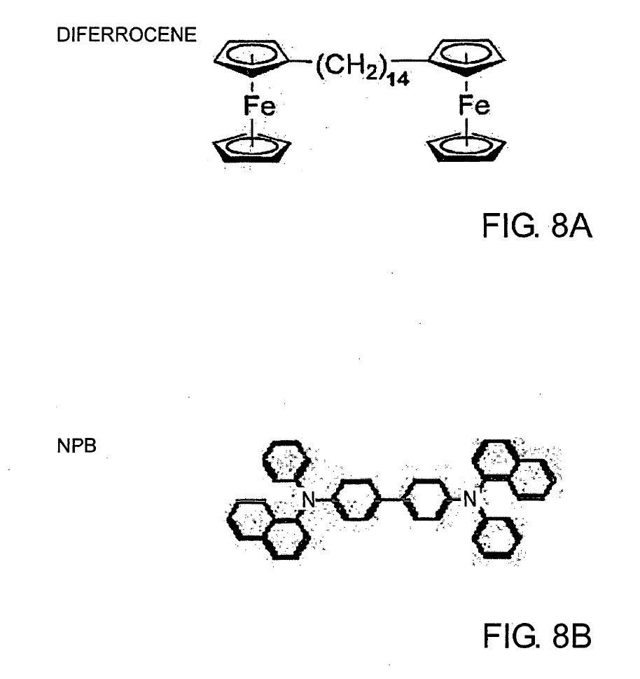

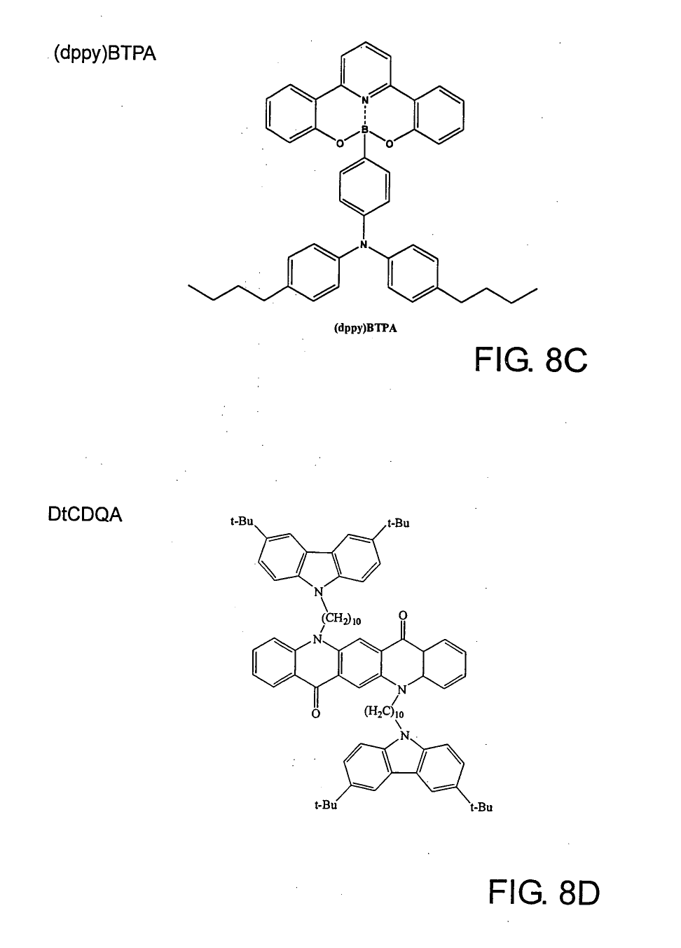

FIGS. 8A to 8D shows molecular formula of the molecules used in present invention. FIG. 8A shows the molecular formula of Diferrocene having a formula mass of 566. FIG. 8B shows the molecular formula of N,N′-bis-(1-naphyl)-N,N′-diphenyl-1,1′-biphenyl′-4,4′-diamine (NPB) which has a formula mass of 586. FIG. 8C shows the molecular formula of 1,6-bis(2-hydroxyphenol)pyridinel boron bis(4-n-butyl-phenyl)phenyleneamine ((dppy)BTPA) having a formula mass of 628. FIG. 8D shows the molecular formula of N,N′-Di[(N-(3,6-di-tbutyl-carbazyl))n-decyl]quinacridone (DtCDQA). The formula mass of DtCDQA is 1146 and its empirical formula is C₈₀N₄O₂H₉₈.

### Instruments and Characterization:

E-beam lithography was performed by LEO VP 1530 field emission scanning electron microscope (SEM) with a Raith Elphy Plus lithography attachment system. Atomic Force Microscopy (AFM) measurements were carried out on a Multimode Nanoscope IIIa instrument (Digital Instrument) operating in tapping mode with silicon cantilevers (resonance frequency in the range of 280-340 kHz). Metal deposition was carried out in a homemade vacuum chamber by heating W wire with a vacuum of 10E-6 mbar, the thickness of the deposited metal was monitored by microbalance. Molecules deposition was performed in a home design ultrahigh Vacuum (UHV) system equipped with a Knudsen cell; the growth rate can be adjusted by controlling cell temperature.

1. A method for selective area growth of organic molecules on a substrate comprising:
creating a pattern of nucleation sites for the organic molecules on the substrate; and
deposition of the organic molecules at the nucleation sites by vapor deposition.

2. The method of claim 1, further comprising controlling the deposition the organic molecules by adapting a temperature of the substrate.

3. The method of claim 1, further comprising controlling the deposition of the organic molecules by adjusting a growth rate of the organic molecules.

4. The method of claim 3, wherein the growth rate of the organic molecules is adjusted by adjusting a temperature of a hot Knudsen cell used for vapor deposition.

5. The method of claim 1, wherein the substrate is selected from the group consisting of silicon, silicon oxide, indium, tin oxide, glass, aluminum oxide or a chemically modified substrate of the above mentioned materials.

6. The method of claim 1, wherein the creation of the pattern of nucleation sites comprises the use of a method selected from the group of e-beam lithography, optical lithography, soft lithography or scanning probe microscopy.

7. The method of claim 1, wherein the creation of the pattern of nucleation sites further comprises depositing a nucleation material as a nucleation site on the substrate.

8. The method of claim 7, wherein the nucleation material is gold or other materials that have different surface energy than the substrate.

9. The method of claim 1, wherein the deposition of the organic molecules is performed in vacuum by physical vapor deposition or chemical vapor deposition.

10. The method of claim 1, wherein the organic molecules are aromatic molecules.

11. The method of claim 1, wherein the organic molecules are molecules of an organic semiconductor.

12. An organic material based device obtained by performing a method for selective area growth of organic molecules on a substrate, the method comprising:
creating a pattern of nucleation sites for the organic molecules on the substrate; and
deposition of the organic molecules at the nucleation sites by vapor deposition.

13. The organic material based device of claim 12 being selected from the group consisting of organic light emitting diodes, organic field effect transistors, photovoltaic devices or organic semiconductor lasers.
